(19) United States
(12) Patent Application Publication
(10) Pub. No.: US 2006/0292809 A1
(43) Pub. Date: Dec. 28, 2006

(54) Method for growth and optimization of heterojunction bipolar transistor film stacks by remote injection

(76) Inventors: Darwin G. Enicks, Colorado Springs, CO (US); Damian A. Carver, Colorado Springs, CO (US)

Correspondence Address: SCHNECK & SCHNECK, P.O. BOX 2-E, SAN JOSE, CA, 95109-0005, US

(21) Appl. No.: 11/166,287

(22) Filed: Jun. 23, 2005

(51) Int. Cl. H01L 21/331

(52) U.S. Cl. 438/350; 438/341; 438/312

(57) ABSTRACT

A method, and a resulting device, for fabricating a heterojunction bipolar transistor (HBT). HBT devices have a high transconductance typical of bipolar devices and are additionally capable of high-power operation. To achieve the aforementioned characteristics, HBT devices are generally of the npn type, preferably with a thin, heavily doped base. The thin, heavily doped base maintains a low base-spreading resistance, leading to a high maximum oscillation frequency. In order to maintain a high doping concentration while minimizing outdiffusion of the dopant material, carbon is remotely doped into the base region. Details of the carbon dopant techniques and procedures are described with respect to fabrication of an exemplary HBT device.

### TECHNICAL FIELD

The invention generally relates to methods of fabrication of integrated circuits (ICs). More specifically, the invention is a method of fabricating heterojunction bipolar transistors utilizing elemental or compound semiconducting materials and resulting devices produced by such methods.

### BACKGROUND ART

Bipolar transistors are an advantageous choice over field effect transistors due to their superior current-drive performance, high frequency response characteristics, and power-handling ability. Consequently, research and development of bipolar transistors using not only silicon (or other group IV materials) but also compound semiconductors (e.g., compounds of elements, especially elements from periodic table groups III-V and II-VI) has seen increased activity in recent years.

Significant growth in both high-frequency wired and wireless markets has introduced new opportunities where compound semiconductors such as SiGe have unique advantages over bulk complementary metal oxide semiconductor (CMOS) technology. With the rapid advancement of epitaxial layer pseudomorphic SiGe deposition processes, epitaxial-base SiGe heterojunction bipolar transistors (HBTs) have been integrated with mainstream advanced CMOS development for wide market acceptance, providing the advantages of SiGe technology for analog RF (radio frequency) circuitry while maintaining the utilization of the advanced CMOS technology base for digital logic circuitry.

In particular, heterojunction bipolar transistors that use compound semiconductors possess a significant advantage in being able to hold the emitter injection efficiency at a high level even when the base is doped to a high concentration by making the gap of the forbidden band of the emitter to be greater than that of the base. An HBT has an emitter region in which the bandgap is greater than the bandgap in the base region. An essential feature of the HBT is that the bandgap offsets at the conduction and valence bands between the emitter region and the base region suppresses hole injection and increases electron injection. As a result, the HBT has a higher injection efficiency than does a transistor having a constant bandgap in the emitter and base regions.

Additional advantages of an HBT over other transistor types include a larger current-drive capacity per unit area, a smaller sensitivity of switching speed to output loading, and a nearly fixed turn-on voltage. Aside from using gallium arsenide for fabricating super high frequency transistors, SiGe HBTs, because of their lower fabrication costs, have found increased use in high frequency areas. The sequence of layers in such transistors generally consists of a silicon collector layer, a base layer of p-doped silicon germanium, and an emitter layer.

Silicon (Si) interstitial pairing with boron (B) results in a rate of diffusion that is much greater than occurs with boron alone. The intrinsic diffusion coefficient (D_{Si}) of silicon in silicon is approximately 560 whereas the intrinsic diffusion coefficient of boron (D_{B}) in silicon is approximately 1. Incorporating carbon (C) into boron-doped silicon minimizes a Si—B pair formation and thus reduces an overall rate of boron outdiffusion. In an HBT device, the reduced boron outdiffusion results in less spreading of a p-type SiGe base region. Narrow base widths reduce transit times of minority carriers and improve a device shutoff frequency, fₜ.

U.S. Pat. No. 6,750,484 to Lippert et al., entitled “Silicon Germanium Hetero Bipolar Transistor” describes a silicon-germanium (SiGe) heterojunction bipolar transistor comprising a silicon collector layer, a boron-doped silicon-germanium base layer, and a silicon emitter layer. The device of Lippert depends on a direct injection of carbon which occurs concurrently with a boron incorporation step during a CVD SiGe growth process. Also, Lippert adds carbon “simultaneously with the epitaxy of all three individual layers: the collector layer, the base layer and the emitter layer” (col. 3, lines 59-61) to reduce boron outdiffusion.

However, such direct injection techniques frequently lead to deleterious effects such as increased base resistance (likely due to increased impurity scattering and/or a reduction in an electrically active dopant) causing a reduction in a maximum operating frequency, updiffusion of oxygen into the SiGe base region (oxygen may decrease minority carrier lifetimes and increase base current), and outdiffusion of germanium (affecting a shape and, consequently, a function of emitter-base and collector-base energy band offsets).

Additionally, direct injection necessitates an increased process complexity, leading to reduced process control, by requiring, for example, a methyl silane injection (or another carbon precursor) to be injected concurrently with diborane (or another boron precursor), silane (or another silicon precursor), and a hydrogen carrier gas. Such a complex precursor flow results in complex and frequently competing reactions coupled with an increase in process recipe complexity due to, inter alia, additional flow and temperature monitoring requirements.

Therefore, what is needed is a reproducible and economical method to produce HBT devices that have a high shutoff frequency and reduced base resistance, without deleterious effects such as outdiffusion of germanium or updiffusion of oxygen.

### SUMMARY

A heterojunction bipolar transistor (HBT) is frequently used in ultra-high speed circuits, as well as in optical transmission circuits with rates in excess of 10 Gbits/sec. HBT devices have a high transconductance typical of bipolar devices and are additionally capable of high-power operation. To achieve the aforementioned characteristics, HBT devices are generally of the npn type, preferably with a thin, heavily doped base. The thin, heavily doped base maintains a low base-spreading resistance, leading to a high maximum oscillation frequency. As base dimensions decrease, there is a concomitant decrease in a diffusion time of minority carriers across the base. Therefore, the base should be as narrow as possible for high performance.

In order to maintain a high doping concentration while minimizing outdiffusion of the dopant material, carbon may be doped into the base region to a level between about 0.1% and 5%. Details of the carbon dopant techniques and procedures are described with respect to fabrication of an exemplary HBT device, infra. Although a particular fabrication process is presented, a skilled artisan will recognize that the carbon injection techniques described herein are readily amenable to other fabrication processes such as lateral HBT and vertical thin-film transistor (VTF) formation and various other FET devices, including those with self-aligned techniques (utilizing, for example, oxide spacers).

The present invention is therefore a method of fabricating a silicon-germanium heterojunction bipolar transistor. An exemplary method includes forming a n+ buried layer in a p-type substrate, depositing an n-type semiconductor epitaxial layer over the buried layer, forming a p-type base region, forming n-type emitter and collector regions, and injecting carbon remote from the p-type base region and allowing the carbon to diffuse into the base region. “Remote” injection refers to (1) adding carbon to the base region either before or after other dopants have been added (i.e., the carbon is not added (e.g., implanted or diffused) at the same type as another dopant species (e.g., boron), and (2) adding carbon indirectly to the base region by adding the carbon to an adjacent or proximal region and not directly into the neutral base itself.

The present invention is also a heterojunction bipolar transistor fabricated by methods presented herein. An exemplary HBT includes substantially-silicon collector and emitter layers with a heavily-doped base layer made substantially of boron-doped silicon-germanium. The base layer is disposed between the emitter layer and the collector layer. The base layer incorporates the remotely-injected carbon in a level of between about 0.1% and 5%, to prevent the outdiffusion of boron and additionally eliminates or minimizes the deleterious effects of the prior art.

### BRIEF DESCRIPTION OF THE DRAWINGS

FIGS. 1A-1F show cross-sections during various stages in an exemplary fabrication of a heterojunction bipolar transistor.

FIG. 2 is a triangular concentration curve of germanium in silicon-germanium heterojunction bipolar transistor.

FIG. 3 is a trapezoidal concentration curve of germanium in silicon-germanium heterojunction bipolar transistor.

### DETAILED DESCRIPTION

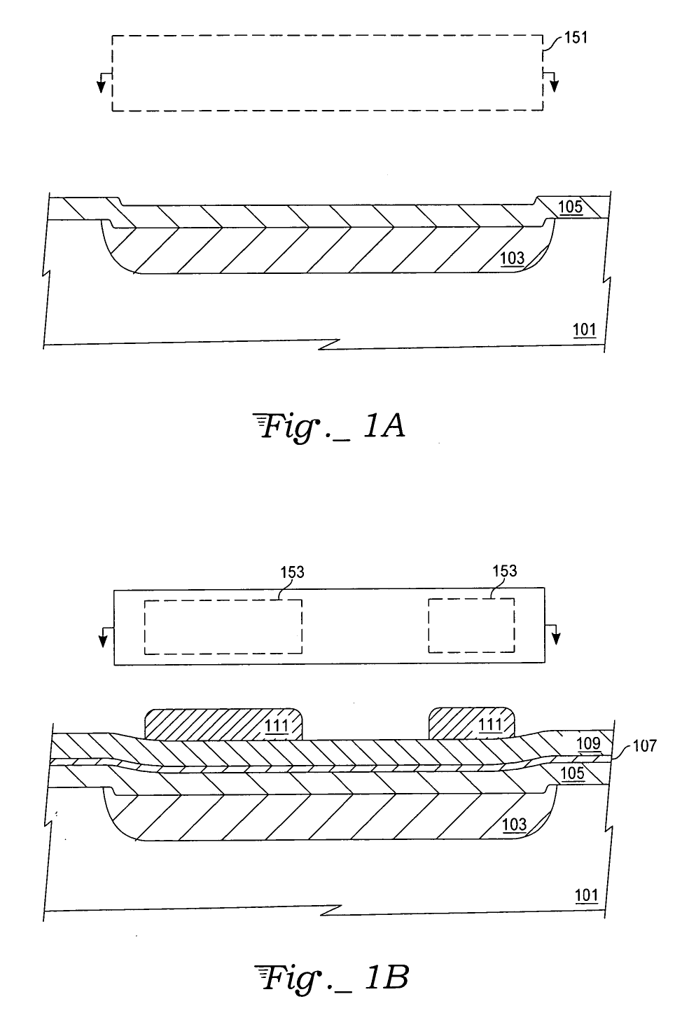

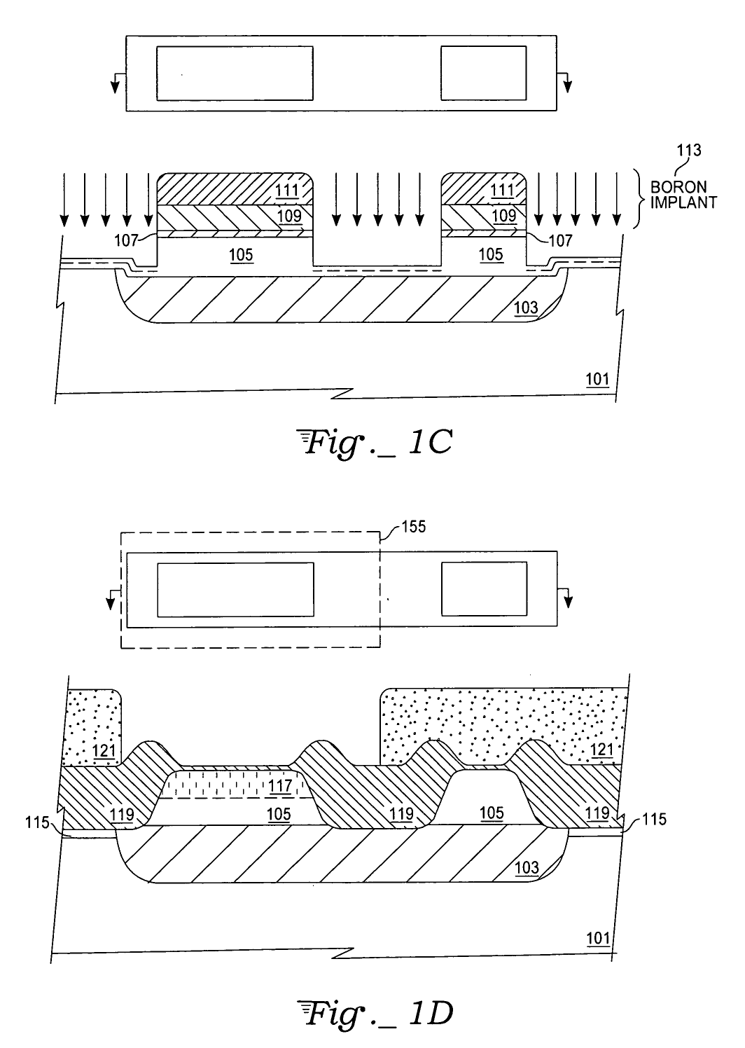

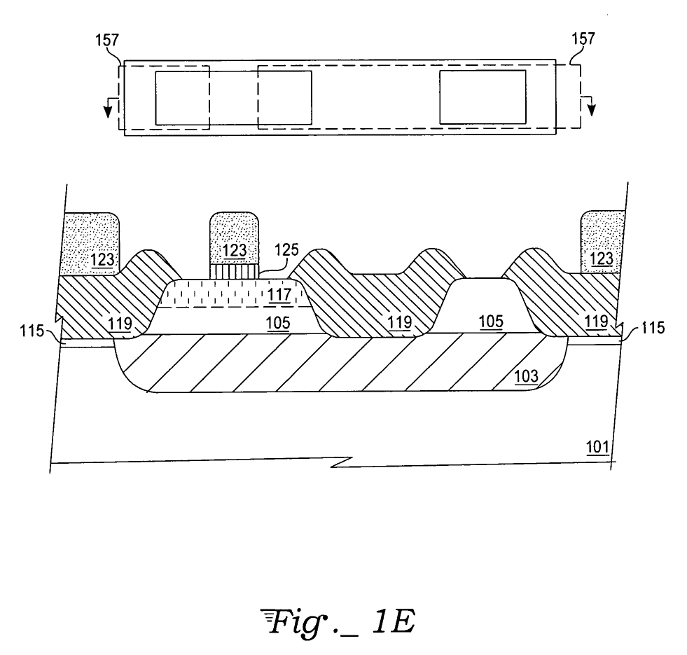

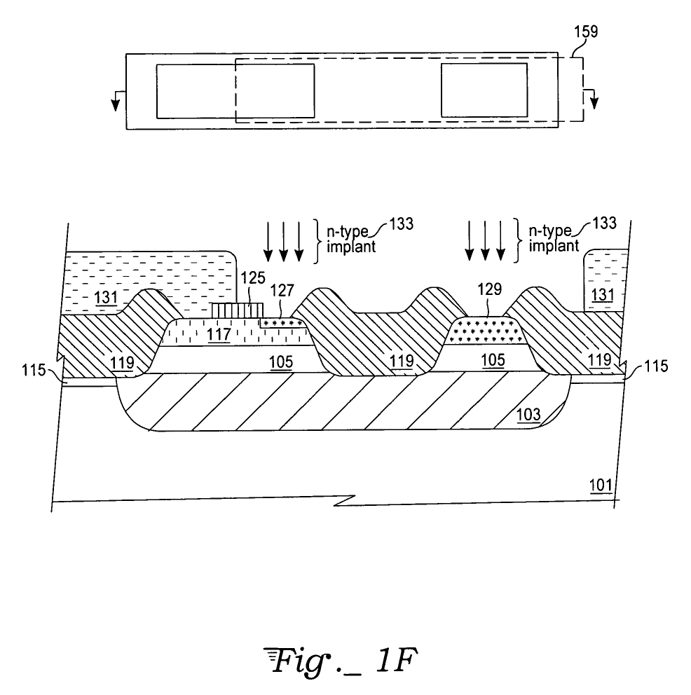

With reference to FIGS. 1A-1F, overall exemplary process steps of a typical HBT device are detailed to illustrate remote injection techniques of the present invention. For simplicity, a single bipolar device region is shown in the drawings. Other electronic device regions (e.g., CMOS transistors) as well as digital logic circuitry may be formed adjacent to the bipolar device region depicted in the drawings. Further, one skilled in the art of bipolar transistor fabrication will realize that the exemplary process steps described herein may be substantially different from other known bipolar processes but, nonetheless, the remote injection techniques described are readily amenable to other processes.

FIG. 1A is an early-stage cross-section of an npn HBT device and includes a substrate 101, an n+ buried layer 103, and a deposited n-epitaxial layer 105. In a specific exemplary embodiment, the substrate 101 is a p-type silicon wafer and the n-epitaxial layer is comprised of doped silicon germanium (SiGe). Alternatively, the substrate 101 could also be a p-doped SiGe or other compound semiconductor, or silicon-on-insulator (SOI). The substrate 101 could also be comprised of a non-semiconductor base material, such as a quartz photoblank or reticle, bonded to an elemental or compound semiconductor. A plan view of a buried layer mask 151 improves visualization of an area involved in the HBT device fabrication. Generally, the sheet resistance of the buried layer 103 is maintained at a low level to reduce the collector resistance of the HBT device. The low sheet resistance requires the buried layer 103 to be relatively heavily doped. However, doping the buried layer 103 too heavily contributes to excessive outdiffusion into the more lightly doped n-epitaxial layer 105. Therefore, antimony or arsenic are frequently used as a dopant for the buried layer 103 since each of these elements has a substantially smaller diffusion coefficient than, for example, phosphorous. Effects of outdiffusion are discussed in more detail, infra.

With reference to FIG. 1B, further processing of the HBT device includes a deposited or thermally grown pad oxide 107, a silicon nitride screen layer 109, and a first photoresist layer 111. The first photoresist layer 111 is patterned with an isolation mask 153 and is provided in preparation of defining collector, base, and emitter regions of the HBT device. Further, the patterned first photoresist layer 111 defines areas of layers overlaying the substrate 101 that will receive, for example, ion-implanted dopants, such as boron. A skilled artisan will recognize that other types of doping means, such as diffusion, are readily implemented as well.

FIG. 1C depicts a cross-sectional view of the HBT device during fabrication after the silicon nitride screen layer 109, the pad oxide 107, and a portion of the n-epitaxial layer 105 have been etched. These layers are etched in accordance with methods well-known in the semiconductor arts. For example, depending upon a chemical composition of a given layer, etching may be accomplished through various wet etch (e.g., in hydrofluoric acid, such as contained in a standard buffered oxide etch, or orthophosphoric acid) or dry-etch techniques (e.g., reactive-ion etch (RIE)). Silicon-containing layers may be etched, for instance, with potassium hydroxide (KOH) or tetra-methyl ammonium hydroxide (TMAH). After the silicon nitride screen layer 109, the pad oxide 107, and a portion of the n-epitaxial layer 105 have been etched, boron 113 is added as a dopant into the n-epitaxial layer through, for example, ion implantation. After a thermal drive-in step, the boron implant 113 forms a p+ region 115 (FIG. 1D) in the HBT device. Any remaining portions of the first photoresist layer 111, the silicon nitride screen layer 109, and the pad oxide 107 are then stripped and a silicon dioxide isolation layer 119 is conformally deposited (e.g., by a chemical vapor deposition (CVD) deposit) and etched back or planarized (e.g., by a chemical mechanical planarization process). A second photoresist layer 121 is patterned using a base mask 155. After etching the second photoresist layer 121, a boron base implant 116 step provides a p-type dopant for a p-base region 117. In this embodiment, the p-base region 117 has a thickness of between about 5 nm and 70 nm.

Either before or after the boron base implant 116 step, an additional carbon implantation or diffusion step (not shown) may be performed, thus injecting carbon atoms into the n-epitaxial layer 105 and surrounding regions within the SiGe. Alternatively, the carbon implantation or diffusion step may be performed into the silicon dioxide isolation layer 119. The carbon is derived from a carbon precursor (e.g., CH₃SiH₃). Carbon precursor injection can be accomplished by techniques such as LPCVD (low pressure chemical vapor deposition), UHCVD (ultra-high vacuum CVD), MBE (molecular beam epitaxy), or ion implantation. The carbon injection is followed by a thermal anneal step. The thermal anneal step allows the carbon to diffuse into the p-type base region 117. Note that, even though a carbon precursor may be injected outside of the p-type base region 117, the position of the carbon after anneal is within the SiGe base region due to an energetically favorable diffusion mechanism. Therefore, remote injection is a means of doping the SiGe with carbon and provides numerous advantages over conventional fabrication methods, discussed supra (e.g., preventing boron outdiffusion thus allowing a higher boron dopant concentration and preventing updiffusion of residual oxygen into the base region). Note that “updiffusion” refers to a diffusion gradient from a lower concentration to higher concentration area. In this context, the updiffusion is with reference to oxygen. Further, remote injection results in a reduced base resistance as compared with direct injection. Therefore, a location of injection and not necessarily a final resting place of carbon following thermal cycles determines a definition of remote carbon injection. Additional embodiments describing other carbon injection techniques and locations are discussed in more detail, infra.

After additional etching of the silicon dioxide insulation layer 119 so as to expose the p-base region 117 and a remaining portion of the n-epitaxial layer 105 (FIG. 1E), a contact mask 157 is used to pattern a third photoresist layer 123. The patterned third photoresist layer 123 defines a base contact 125 formed from a deposited metal layer (not shown but formed by techniques and methods known to a skilled artisan).

With reference to FIG. 1F, an emitter-collector mask 159 is used to pattern a fourth photoresist layer 131. The patterned fourth photoresist layer 131 protects certain regions of the HBT device while an n-type implant 133 step forms an n+ emitter region 127 and an n+ collector region 129. The fourth photoresist layer 131 is then stripped and fabrication of the HBT device continues with, for example, final metallization and passivation layers (not shown).

Alternative remote carbon injection techniques (with CH₃SiH₃ or other carbon precursor) may take place at other times or locations other than those discussed in the previous embodiment. For example, the remote carbon injection may take place into either Si (e.g., the substrate 103 or the n+ buried layer 103 (FIGS. 1A-1F)) or various places within the SiGe layers (the n-epitaxial layer 105). Carbon injection temperatures generally range from about 300° C. to 1000° C. Variations in exact times and temperatures can be used to tailor the carbon incorporation and, consequently, an effect of the carbon on boron and germanium (Ge) outdiffusion and strain. The injection can occur during or after, either growth or implantation of the emitter region 127, the collector region 129, or the base region 117. If self-aligning techniques incorporating oxide (or another dielectric material) spacers are employed, the injection can occur during or after growth of a base-emitter spacer (BE) or a base-collector spacer (BC). (Note: formation of neither the BE nor BC spacer are shown but such techniques are well-known in the art). Carbon injection may be performed at multiple points during fabrication of either the base, BC, BE, collector, and/or emitter regions. Thermal anneal cycles are then implemented to provide activation energy for the carbon to diffuse from the dielectric spacer into the one or more various SiGe regions. A final position of carbon after anneal is within the SiGe through a diffusion mechanism. Advantages of remote carbon injection include: (1) reduced boron outdiffusion; (2) a mitigation of an updiffusion of oxygen (oxygen would normally diffuse from surrounding layers into the SiGe base region 117 during thermal anneal cycles, thereby limiting a maximum frequency of the HBT device); (3) a significant reduction in the base resistance (consequently enhancing fₘₐₓ); and (5) a resultant net increase in compressive strain in SiGe (due to an increase in a strained SiGe lattice parameter due to removal of carbon).

Further, ramped carbon profiles may be tailored to have either triangular or trapezoidal shapes by, for example, ramping gas injection during a CVD process. Tailoring a carbon profile has numerous advantages, including: (1) enhancing the reduction in boron outdiffusion; (2) optimizing or tailoring the strain at the Si—SiGe boundaries; and (3) reducing and/or optimizing the intermixing of Ge and B at the Si—SiGe boundaries. All of these advantages of tailoring the carbon profile improve performance characteristics (such reducing base resistance and transit time and thus, increasing the maximum operating frequency) of the HBT device.

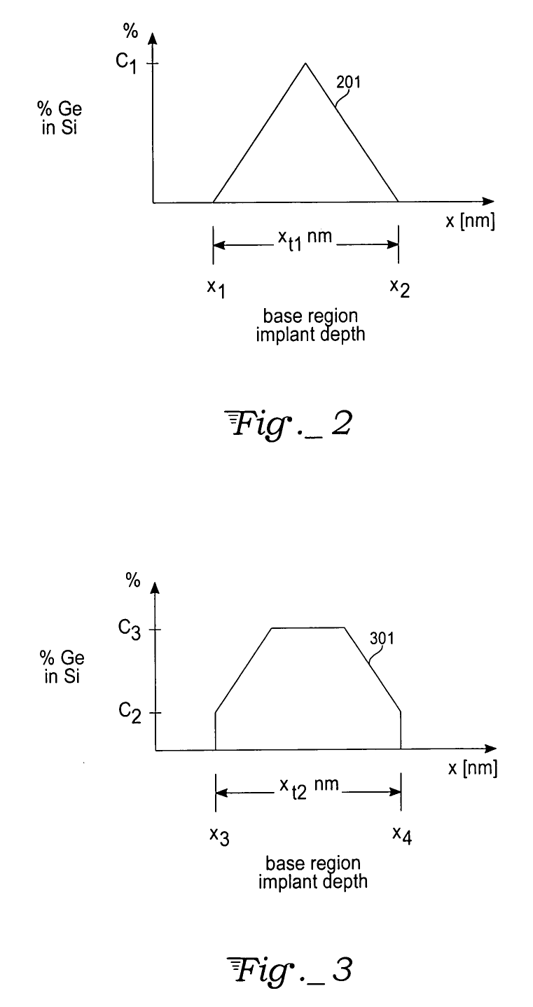

FIGS. 2 and 3 represent exemplary concentration profiles of germanium in silicon of silicon germanium heterojunction bipolar transistors in accordance with the present invention. The profiles may be, for example, triangular or trapezoidal. Other dopant profiles are also possible. In both diagrams, the base region is limited on the abscissa by an approximate base depth. The ordinate axis represents the profile as a percentage of the germanium concentration.

In a specific exemplary embodiment, various layers of a SiGeC HBT device, along with alternative layer options, are shown textually in table 1, infra. In this exemplary embodiment, layers 3, 4, 5, 6, and 7 are fabricated in-situ in a common epi reactor. Layers 2, 3, 4, 6, and 7 are all potential locations for remote carbon injection.

TABLE 1

| | |
|---|---|
| Silicon Emitter and Contact Layer (n-type) | 8 |
| Silicon Base-Emitter Interface Layers(s) | 7 |
| Option No. 7: undoped Si cap layer | |
| Option No. 8: n-type Si cap layer | |
| Option No. 9: p-type Si cap layer | |
| Option No. 10: combines Option Nos. 7, 8, and 9 in | |
| various orders and combinations | |
| SiGe Base-Emitter Interface Layer(s) | 6 |
| Option No. 4: undoped SiGe spacer region | |
| Option No. 5: n-type SiGe spacer region (typically | |
| arsenic or phosphorous) | |
| Option No. 6: combines Option Nos. 4 and 5 in various | |
| orders and combinations | |
| p-type Silicon Germanium Base Region (Doped with | 5 |
| Boron) | |
| Silicon Germanium Base-Collector Interface Layer | 4 |
| Undoped SiGe spacer region | |
| Seed Layer (<1000 Å Thick, Si Epitaxy) | 3 |
| Option No. 3: n-type epi-Si seed layer | |
| Option No. 2: undoped epi-Si seed layer | |
| Option No. 1: combines Option Nos. 2 and 3 in various | |
| orders and combinations | |
| Collector Region (Si Epitaxy) | 2 |
| In-situ doped either p-type or n-type and/or with ion | |
| implantation | |
| Silicon Substrate (p-type) | 1 |

In layer order for this specific exemplary embodiment, layer 1 is a silicon p-type substrate. Layer 2, a doped collector layer, is formed during silicon epitaxial processing and is initially doped with either a p-type or n-type dopant. For an NPN transistor, the final layer is n-type. Next, layer 3, a seed layer or collector interface layer is comprised of epitaxial, low defect, pseudomorphically-grown SiGe. Subsequent SiGe layers, 4, 5, and 6 are similarly grown. Layers 7 and 8, a silicon base-emitter interface layer and silicon emitter and contact layer respectively, are also grown, in various permutations as shown, by epitaxial techniques. Remote carbon injection techniques described herein into any or all layers 2, 3, 4, 6, and 7, result in, inter alia, (1) minimized boron outdiffusion by a substitutional reaction with silicon interstitial defects (anomalous boron diffusion occurs by Si—B pairing thus enhancing boron diffusion; carbon reacts substitutionally to inhibit the Si—B pairing); (2) a narrower boron base region results in a short transit time for carriers, thus enhancing device speed (i.e., an increased Fₜ); and (3) carbon “buys” thermal budget allowances due to a minimized affect of thermal energy on boron diffusion.

With reference to FIG. 2, a triangular germanium concentration profile 201 of an HBT device in a particular embodiment indicates an exemplary maximum width, xₜ₁, of the base layer is 50 nm. The concentration of germanium in the center of the base layer where it reaches its maximum, C₁, is about 40%. A range of germanium concentrations in the triangular profile may extend from about 5% to 40%. This transistor concentration profile 201 allows very high early currents. Moreover, this concentration profile 201 permits impressing a drift field for reducing a base transit time of the minority carrier.

An HBT device with a trapezoidal germanium concentration profile 301 of FIG. 3 has an exemplary base layer width, xₜ₂, of approximately 50 nm. The concentration of germanium in the base layer increases linearly from a side of the collector or emitter of the transistor from about 5% at level C₂ to about 35% at C₃. A range of germanium concentrations in the trapezoidal profile may extend from less than 5% to greater than 35%. In this exemplary embodiment, high current amplification as well as high early current and a drift field are attained, thus reducing a transit time of the base.

Although the present invention is described in terms of exemplary embodiments, a skilled artisan will realize that techniques described herein can readily be adapted to other forms of fabrication techniques and devices. For example, remote injection techniques are readily amenable to both vertical and lateral bipolar device structures as well as self-aligned structures. Although reference is made exclusively to npn HBT devices, one skilled in the art will appreciate that remote injection techniques may be advantageous to numerous types of electronic devices such as emitter-collector regions of a pnp bipolar transistor or to a gate of an NMOS or PMOS transistor. Further, dopant steps are generally defined herein in terms of implantation procedures (e.g., ion implantation). A skilled artisan will recognize that other dopant techniques, such as diffusion, will also readily produce doped-regions in an electronic device.

Also, although process steps and techniques are shown and described in detail, a skilled artisan will recognize that other techniques and methods may be utilized which are still included within a scope of the appended claims. For example, there are frequently several techniques used for depositing a film layer (e.g., chemical vapor deposition, plasma-enhanced vapor deposition, molecular beam epitaxy, atomic layer deposition, atmospheric pressure CVD, etc.). Although not all techniques are amenable to all film types described herein, one skilled in the art will recognize that multiple methods for depositing a given layer and/or film type may be used.

Additionally, many industries allied with the semiconductor industry could make use of the remote carbon injection technique. For example, a thin-film head (TFH) process in the data storage industry or an active matrix liquid crystal display (AMLCD) in the flat panel display industry could readily make use of the processes and techniques described herein. The term “semiconductor” should be recognized as including the aforementioned and related industries.

What is claimed is:

1. A heterojunction bipolar transistor comprising:
a collector layer made substantially of an elemental semiconductor;
an emitter layer made substantially of an elemental semiconductor; and
a base layer made substantially of boron-doped silicon-germanium disposed between the emitter layer and the collector layer, the base layer incorporating remotely-injected carbon in a level of between about 0.1% and 5%, the remotely injected carbon being incorporated in a process either proceeding or subsequent to the boron-dopant.

2. The heterojunction bipolar transistor of claim 1, wherein germanium is incorporated into the base layer in a concentration of between about 5% and 40%.

3. The heterojunction bipolar transistor of claim 1, wherein a concentration profile of germanium in the base layer between the emitter layer and the collector layer has a generally triangular profile.

4. The heterojunction bipolar transistor of claim 1, wherein a concentration profile of germanium in the base layer between the emitter layer and the collector layer has a generally trapezoidal profile.

5. The heterojunction bipolar transistor of claim 1, wherein the base layer has a thickness between about 5 nm and 70 nm.

6. The heterojunction bipolar transistor of claim 1, wherein the collector layer is comprised of silicon.

7. The heterojunction bipolar transistor of claim 1, wherein the emitter layer is comprised of silicon.

8. A heterojunction bipolar transistor comprising:
a collector layer made substantially of a compound semiconductor;
an emitter layer made substantially of a compound semiconductor; and
a base layer made substantially of boron-doped silicon-germanium disposed between the emitter layer and the collector layer, the base layer incorporating remotely-injected carbon in a level of between about 0.1% and 5%, the remotely injected carbon being incorporated in a process either proceeding or subsequent to the boron-dopant.

9. The heterojunction bipolar transistor of claim 8, wherein germanium is incorporated into the base layer in a concentration of between about 5% and 40%.

10. The heterojunction bipolar transistor of claim 8, wherein a concentration profile of germanium in the base layer between the emitter layer and the collector layer has a generally triangular profile.

11. The heterojunction bipolar transistor of claim 8, wherein a concentration profile of germanium in the base layer between the emitter layer and the collector layer has a generally trapezoidal profile.

12. The heterojunction bipolar transistor of claim 8, wherein the base layer has a thickness between about 5 nm and 70 nm.

13. The heterojunction bipolar transistor of claim 8, wherein the collector layer is comprised of silicon-germanium.

14. The heterojunction bipolar transistor of claim 8, wherein the emitter layer is comprised of silicon-germanium.

15. A heterojunction electronic device comprising:
a source layer made substantially of a semiconducting material;
a drain layer made substantially of a semiconducting material; and
a gate layer made substantially of boron-doped silicon-germanium disposed between the source layer and the drain layer, the gate layer incorporating remotely-injected carbon in a level of between about 0.1% and 5%, the remotely-injected carbon being incorporated into the silicon-germanium gate layer by injecting the carbon outside of the silicon-germanium gate layer.

16. The heterojunction electronic device of claim 15, wherein the remotely-injected carbon is incorporated by low pressure chemical vapor deposition (LPCVD).

17. The heterojunction electronic device of claim 15, wherein the remotely-injected carbon is incorporated by ultra-high vacuum pressure chemical vapor deposition (UHVCVD).

18. The heterojunction electronic device of claim 15, wherein the remotely-injected carbon is incorporated by molecular beam epitaxy (MBE).

19. The heterojunction electronic device of claim 15, wherein the remotely-injected carbon is incorporated by ion implantation.

20. The heterojunction electronic device of claim 15, wherein the remotely-injected carbon is incorporated by atmospheric pressure chemical vapor deposition (APCVD).

21. The heterojunction electronic device of claim 15, wherein a concentration profile of germanium in the gate layer between the source layer and the drain layer has a generally triangular profile.

22. The heterojunction electronic device of claim 15, wherein a concentration profile of germanium in the gate layer between the source layer and the drain layer has a generally trapezoidal profile.

23. The heterojunction electronic device of claim 15, wherein the source layer is comprised of silicon-germanium.

24. The heterojunction electronic device of claim 15, wherein the drain layer is comprised of silicon-germanium.

25. The heterojunction electronic device of claim 15, wherein the source layer is comprised of silicon.

26. The heterojunction electronic device of claim 15, wherein the drain layer is comprised of silicon.

27. A method of fabricating a silicon-germanium heterojunction bipolar transistor, the method comprising:
forming a doped buried layer in a substrate, the doped buried layer having a first type of majority carrier;
depositing a semiconductor epitaxial layer over the buried layer, the epitaxial layer having the first type of majority carrier;
forming a base region;
doping the base region with a dopant containing a second type of majority carrier, the second type of majority carrier being dissimilar from the first type of majority carrier;
forming an emitter region;
doping the emitter region with the first type of majority carrier;
forming a collector region;
doping the collector region with the first type of majority carrier; and
injecting carbon remote from the base region and allowing the carbon to updiffuse into the base region.

28. The method of claim 27 wherein the first majority carrier is comprised of electrons.

29. The method of claim 27 wherein the second majority carrier is comprised of holes.

30. The method of claim 27 wherein the base region is substantially comprised of silicon-germanium.

31. The method of claim 27 wherein carbon is injected into the emitter region.

32. The method of claim 27 wherein carbon is injected into the collector region.

33. The method of claim 27 further comprising forming dielectric spacers around the base region to provide a self-aligning structure.

34. The method of claim 33 wherein the step of injecting carbon remote from the base region includes injecting the carbon into the dielectric spacers.

35. A heterojunction bipolar transistor comprising:
a collector layer made substantially of an elemental semiconductor;
an emitter layer made substantially of a compound semiconductor; and
a base layer made substantially of boron-doped silicon-germanium disposed between the emitter layer and the collector layer, the base layer incorporating remotely-injected carbon in a level of between about 0.1% and 5%, the remotely injected carbon being incorporated in a process either proceeding or subsequent to the boron-dopant.

36. The heterojunction bipolar transistor of claim 35, wherein germanium is incorporated into the base layer in a concentration of between about 5% and 40%.

37. The heterojunction bipolar transistor of claim 35, wherein a concentration profile of germanium in the base layer between the emitter layer and the collector layer has a generally triangular profile.

38. The heterojunction bipolar transistor of claim 35, wherein a concentration profile of germanium in the base layer between the emitter layer and the collector layer has a generally trapezoidal profile.

39. The heterojunction bipolar transistor of claim 35, wherein the base layer has a thickness between about 5 nm and 70 nm.

40. The heterojunction bipolar transistor of claim 35, wherein the collector layer is comprised of silicon.

41. The heterojunction bipolar transistor of claim 35, wherein the emitter layer is comprised of silicon-germanium.

42. A heterojunction bipolar transistor comprising:
a collector layer made substantially of an elemental semiconductor;
an emitter layer made substantially of a compound semiconductor; and
a base layer made substantially of boron-doped silicon-germanium disposed between the emitter layer and the collector layer, the base layer incorporating remotely-injected carbon in a level of between about 0.1% and 5%, the remotely injected carbon being incorporated in a process either proceeding or subsequent to the boron-dopant.

43. The heterojunction bipolar transistor of claim 42, wherein germanium is incorporated into the base layer in a concentration of between about 5% and 40%.

44. The heterojunction bipolar transistor of claim 42, wherein a concentration profile of germanium in the base layer between the emitter layer and the collector layer has a generally triangular profile.

45. The heterojunction bipolar transistor of claim 42, wherein a concentration profile of germanium in the base layer between the emitter layer and the collector layer has a generally trapezoidal profile.

46. The heterojunction bipolar transistor of claim 42, wherein the base layer has a thickness between about 5 nm and 70 nm.

47. The heterojunction bipolar transistor of claim 42, wherein the collector layer is comprised of silicon.

48. The heterojunction bipolar transistor of claim 42, wherein the emitter layer is comprised of silicon-germanium.
